(19) United States
(12) Patent Application Publication
(10) Pub. No.: US 2025/0391653 A1
(43) Pub. Date: Dec. 25, 2025

(54) METHODS OF REPAIRING LOW-K MATERIALS AFTER INTEGRATION OPERATIONS

(71) Applicant: Applied Materials, Inc., Santa Clara, CA (US)

(72) Inventor: Muthukumar Kaliappan, Fremont, CA (US)

(73) Assignee: Applied Materials, Inc., Santa Clara, CA (US)

(21) Appl. No.: 18/750,074

(22) Filed: Jun. 21, 2024

(51) Int. Cl. H01L 21/02; C23C 16/02; C23C 16/04; C23C 16/24; C23C 16/505; H01J 37/32

(52) U.S. Cl. CPC H01L 21/02219; C23C 16/0227; C23C 16/045; C23C 16/24; C23C 16/505; H01J 37/32449; H01J 2237/332

(57) ABSTRACT

Exemplary processing methods may include providing a silicon-containing precursor having multiple functional groups to a processing region of a semiconductor processing chamber. A substrate may be housed within the processing region. The substrate may include a layer of silicon-containing material defining one or more pores. The methods may include contacting the layer of silicon-containing material with the silicon-containing precursor. The silicon-containing precursor may diffuse into the one or more pores and may reduce Si—OH bonds and/or Si—H bonds within the one or more pores.

### TECHNICAL FIELD

The present technology relates to semiconductor processing. More specifically, the present technology relates to methods of preparing low-κ materials, such as low-κ silicon-containing materials, after integration operations are performed.

### BACKGROUND

Integrated circuits are made possible by processes which produce intricately patterned material layers on substrate surfaces. Producing patterned material on a substrate requires controlled methods for forming and removing material. Material characteristics may affect how the device operates, and may also affect how the films are removed relative to one another. Integration operations, or operations after materials are deposited, may modify properties of the materials. As such, some films that are formed require additional processing to adjust or enhance the material characteristics of the film in order to provide suitable properties.

Thus, there is a need for improved systems and methods that can be used to produce high quality devices and structures. These and other needs are addressed by the present technology.

### SUMMARY

Exemplary processing methods may include providing a silicon-containing precursor having multiple functional groups to a processing region of a semiconductor processing chamber. A substrate may be housed within the processing region. The substrate may include a layer of silicon-containing material defining one or more pores. The methods may include contacting the layer of silicon-containing material with the silicon-containing precursor. The silicon-containing precursor may diffuse into the one or more pores and may reduce Si—OH bonds and/or Si—H bonds within the one or more pores.

In some embodiments, the methods may include forming plasma effluents of the silicon-containing precursor. The silicon-containing precursor may further include nitrogen. The silicon-containing precursor may include a single nitrogen with multiple functional groups bonded to the single nitrogen. The silicon-containing precursor may include a plurality of Si—N bonds. The silicon-containing precursor may include a ring having at least one nitrogen atom. Contacting the layer of silicon-containing material with the silicon-containing precursor may fragment the silicon-containing precursor. Subsequent to fragmenting the silicon-containing precursor, a remaining portion of the silicon-containing precursor may diffuse further into one of the one or more pores. Contacting the layer of silicon-containing material with the silicon-containing precursor may increase an amount of Si-CH₃ bonds within the one or more pores. Contacting the layer of silicon-containing material with the silicon-containing precursor may increase an amount of Si—O—Si crosslinking within the one or more pores. Contacting the layer of silicon-containing material with the silicon-containing precursor may reduce a dielectric constant of the layer of silicon-containing material. The methods may include performing an integration operation prior to providing the silicon-containing precursor having multiple functional groups to the processing region. The integration operation may increase Si—OH bonds and/or Si—H bonds within the one or more pores. The integration operation may include one or more of planarization, etching, ashing, or cleaning.

Some embodiments of the present technology may encompass semiconductor processing methods. The methods may include providing a silicon-and-nitrogen-containing precursor having multiple functional groups to a processing region of a semiconductor processing chamber. The silicon-containing precursor may further include nitrogen. A substrate may be housed within the processing region. The substrate may include a layer of silicon-containing material defining one or more pores. The methods may include contacting the layer of silicon-containing material with the silicon-containing precursor. Contacting-the layer of silicon-containing material with the silicon-containing precursor may increase an amount of Si—O—Si crosslinking within the one or more pores.

In some embodiments, the silicon-and-nitrogen-containing precursor may be characterized by a plurality of SiX_{y} groups bonded to a nitrogen atom, wherein X is hydrogen, an alkyl, an alkoxy, or a halide. The processing region may be maintained plasma-free while providing the silicon-and-nitrogen-containing precursor and while contacting the layer of silicon-containing material with the silicon-containing precursor. Contacting the layer of silicon-containing material with the silicon-containing precursor may reduce Si—OH and/or Si—H bonds within the one or more pores.

Some embodiments of the present technology may encompass semiconductor processing methods. The methods may include providing a silicon-and-nitrogen-containing precursor having multiple functional groups to a processing region of a semiconductor processing chamber. The silicon-containing precursor may further include nitrogen. A substrate may be housed within the processing region. The substrate may include a layer of silicon-containing material defining one or more pores. The methods may include contacting the layer of silicon-containing material with the silicon-containing precursor. Contacting the layer of silicon-containing material with the silicon-containing precursor may fragment the silicon-containing precursor. A remaining portion of the silicon-containing precursor may diffuse further into one of the one or more pores.

In some embodiments, contacting the layer of silicon-containing material with the silicon-containing precursor may reduce Si—OH bonds and/or Si—H bonds within the one or more pores. Contacting the layer of silicon-containing material with the silicon-containing precursor may increase an amount of Si—O—Si crosslinking within the one or more pores.

Such technology may provide numerous benefits over conventional systems and techniques. For example, by utilizing a silicon-containing precursor having multiple functional groups to repair damage to low-K material, a single compound of the precursor may repair multiple undesirable terminations. Additionally, by utilizing a silicon-containing precursor having multiple functional groups, fragmented portions of the silicon-containing precursor may diffuse further into the low-K material than conventionally possible. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary processing chamber according to some embodiments of the present technology.

FIG. 2 shows exemplary operations in a processing method according to some embodiments of the present technology.

FIGS. 3A-3C show schematic cross-sectional views of a substrate during a processing according to some embodiments of the present technology.

Several of the figures are included as schematics. It is to be understood that the figures are for illustrative purposes and are not to be considered of scale unless specifically stated to be of scale. Additionally, as schematics, the figures are: provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

During back-end-of-line (BEOL) semiconductor processing, low-κ films may serve multiple functions in the fabrication of metallization layers in an integrated circuit. These functions may include the incorporation of electrically-insulating low-κ films between electrically-conductive metal-containing structures such as interconnect lines, contact holes, and vias, among other structures. They may also include the partial removal of a low-film following the formation of metal structure. One common removal process in BEOL processing is chemical-mechanical-polishing (CMP) that uses a combination of chemical etching and physical abrasion to remove the low-κ material from a substrate surface.

Low-κ materials used in BEOL processing should have a low dielectric constant (K value) relative to other materials, such as undoped silicon oxide, and high mechanical stability to resist fracturing during the formation of metal-containing structures and removal by CMP. Unfortunately, post-deposition integration operations, such as planarization (e.g.,? CMP), etching, ashing, cleaning, may increase Si—OH bonds and/or Si—H bonds and, therefore, increase the dielectric constant of the low-κ materials. Conventional technologies have attempted to treat these damage low-κ materials with silicon-containing precursors. While effective to an extent, conventional precursors cannot fully diffuse within pores defined by the low-κ materials, which may be characterized by dimensions smaller than the silicon-containing precursor itself.

The present technology may overcome these limitations by utilizing silicon-containing precursors having multiple functional groups. These silicon-containing precursors having multiple functional groups may fragment during treatment. The fragmentation may reduce a size of the silicon-containing precursor and may allow the silicon-containing precursor to continue diffusing deeper into the pore. As such, the present technology may repair damage low-κ materials to a greater extent than conventional technologies.

After describing general aspects of a chamber according to some embodiments of the present technology in which gap filling operations discussed below may be performed, specific methodology may be discussed. It is to be understood that the present technology is not intended to be limited to the specific films, chambers or processes discussed, as the techniques described may be used to improve a number of film formation processes, and may be applicable to a variety of processing chambers and operations.

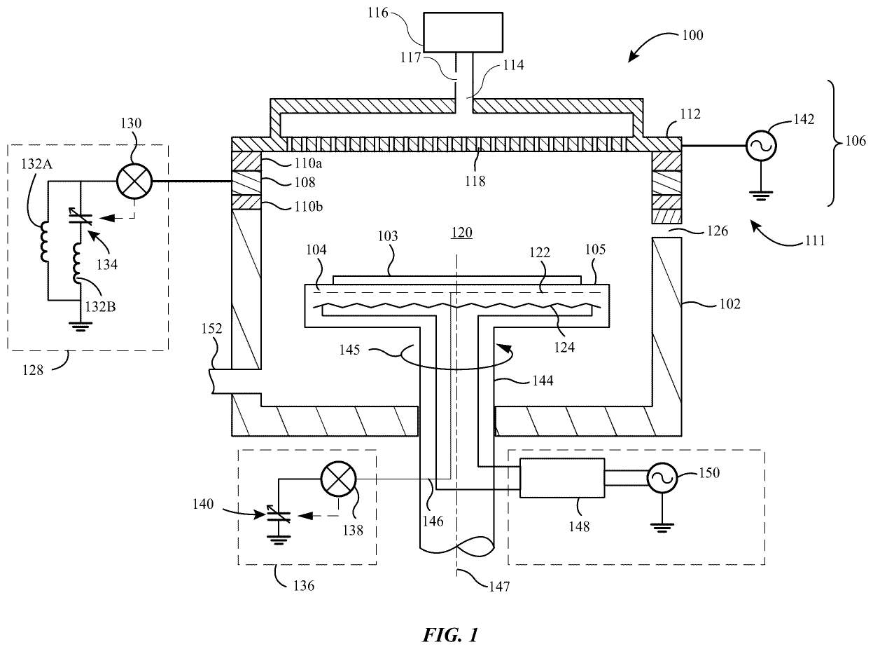

FIG. 1 shows a cross-sectional view of an exemplary processing chamber 100 according to some embodiments of the present technology. The figure may illustrate an overview of a system incorporating one or more aspects of the present technology, and/or which May perform one or more deposition or other processing operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112, also referred to as a faceplate, and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components.

For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions- present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

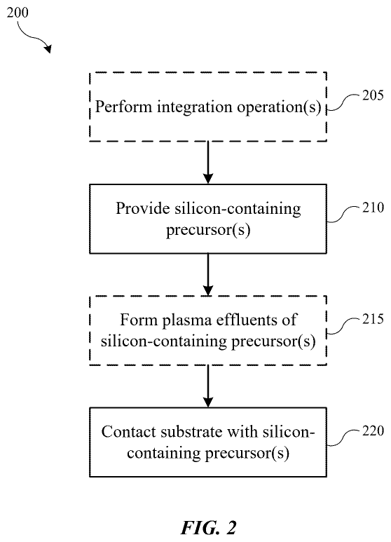

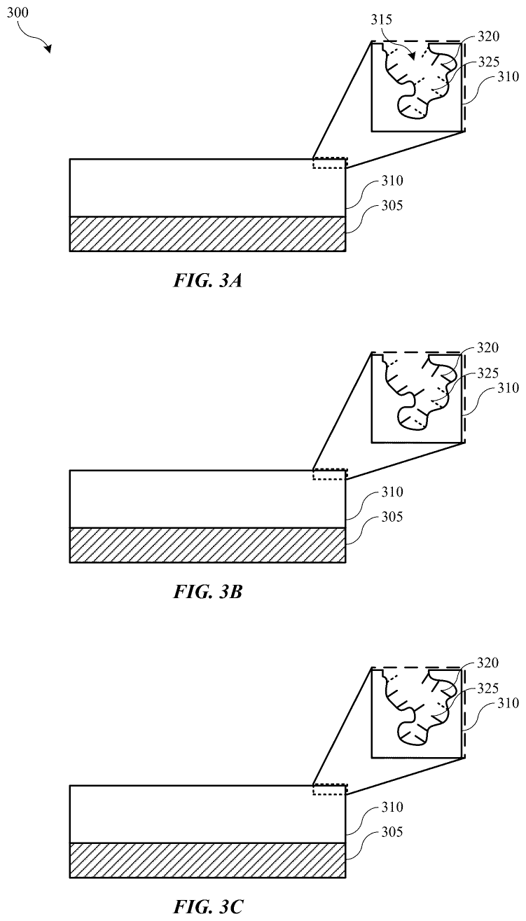

Processing chamber 100 may be utilized in some embodiments of the present technology for processing methods that may include repairing low-x materials after one. or more integration operations. It is to be understood that the chamber described is not to be considered limiting, and any chamber that may be configured to perform operations as described may be similarly used. FIG. 2 shows exemplary operations in a processing method 200 according to some embodiments of the present technology. The method may be performed in a variety of processing chambers and on one or more mainframes or tools, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 200 may describe operations shown schematically in FIGS. 3A-3C, the illustrations of which will be described in conjunction with the operations of method 200. It is to be understood that the figures illustrate only partial schematic views, and a substrate may contain any number of additional materials and features having a variety of characteristics and aspects as illustrated in the figures.

Method 200 may include additional operations prior to initiation of the listed operations. For example, additional processing operations may include forming structures on a substrate, which may include both forming and removing material. For example, transistor structures, memory structures, or any other structures may be formed. Prior processing operations may be performed in the chamber in which method 200 may be performed, or processing may be performed in one or more other processing chambers prior to delivering the substrate into the semiconductor processing chamber or chambers in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing volume 120 described above.

As illustrated in FIG. 3A, a substrate on which several operations have been performed may be substrate 305 of a structure 300, which may show a partial view of a substrate on which semiconductor processing may be performed. It is to be understood that structure 300 may show only a few top layers during processing to illustrate aspects of the present technology.

Substrate 305 may be any number of materials used in semiconductor processing. The substrate material may be or include silicon, germanium, dielectric materials including silicon oxide or silicon nitride, metal materials, or any number of combinations of these materials, which may be the substrate 305, or materials formed in structure 300. The substrate 305 may include a layer of material 310. The layer of material 310 may be, for example, a layer of a silicon-containing material. The layer of material 310 may be a porous material defining one or more pores 315. Within the one or more pores 315 may be terminal groups of the layer of material 310. When the layer of material includes a layer of silicon-containing material, the terminal groups within the one or more pores 315 may include desirable terminations 320, such as Si—CH₃ bonds, Si—NH bonds, Si—NH₂ bonds, and/or Si—O—Si crosslinking, which may reduce the dielectric constant of the layer of material. When the layer of material includes a layer of silicon-containing material, the terminal groups within the one or more pores 315 may also include undesirable terminations 325, such as Si—OH and/or Si—H bonds, which may increase the dielectric constant of the layer of material.

At optional operation 205, method 200 may include performing an integration operation. The integration operation may include one or more of planarization (e.g., CMP), etching, ashing, cleaning, or other operation subsequent to forming the layer of material 310. These integration operations expose the layer of material 310 to various precursors that may be plasma-enhanced.

The integration operation at optional operation 205 may increase an amount of undesirable terminations 325, such as Si—OH bonds and/or Si—H bonds, within the one or more pores 315. This increase in undesirable terminations 325 within the one or more pores 315 may undesirably increase the dielectric constant of the layer of material 310.

Conventional technologies may attempt to use various precursors to reorganize undesirable terminations 325, such as Si—OH bonds and/or Si—H bonds, to desirable terminations 320, such as Si-CH₃ bonds, Si—NH bonds, Si—NHh₂ bonds, and/or Si—O—Si crosslinking. However, conventional technologies may utilize precursors that are unable to diffuse fully into the one or more pores 315. For example, the effectiveness of conventional technologies may be limited to average pore size. In embodiments of the present technology, the one or more pores 315 may be characterized by an average pore size of less than or about 40 nm, and may be characterized by an average pore size of less than or about 35 nm, less than or about 30 nm, less than or about 25 nm, less than or about 20 nm, less than or about 18 nm, less. than or about 16 nm, less than or about 14 nm, less than or about 12 nm, less than or about 10 nm, less than or about 8 nm, less than or about 6 nm, less than or about 4 nm, less than or about 2 nm, or less. As further described below, the present technology may utilize multi-functional precursors (i.e., precursors having multiple functional groups) that may fragment and diffuse further into the one or more pores 315.

To address the increase in dielectric constant of the layer of material 310 resulting from the integration operation at optional operation 205, method 200 may include performing a repair operation. The repair operation may include providing a silicon-containing precursor to the processing region at operation 210. In embodiments, method 200 may include forming plasma effluents of the silicon-containing precursor at optional operation 215. At operation 220, method 200 may include contacting the layer of material 310 with the silicon-containing precursor or, if formed, the plasma effluents of the silicon-containing precursor.

The silicon-containing precursor provided to the processing region at operation 210 may have multiple functional groups. In embodiments, the silicon-containing precursor may include two or more functional groups, and may include three or more functional groups, four or more, five or more, six or more, or any number functional groups. The silicon-containing precursor may further include other elements in addition to silicon, such as carbon, hydrogen, oxygen, and/or nitrogen. For example, the silicon-containing precursor may be a silicon-and-nitrogen-containing precursor. In embodiments, the silicon-containing precursor the silicon-containing precursor may include a single nitrogen with multiple functional groups bonded to the single nitrogen. In other embodiments, the silicon-containing precursor may include a plurality of Si—N bonds. In yet other embodiments, the silicon-containing precursor may include a ring having at least one nitrogen atom.

Silicon-containing precursors including a single nitrogen with multiple functional groups bonded to the single nitrogen may include, but are not limited to:

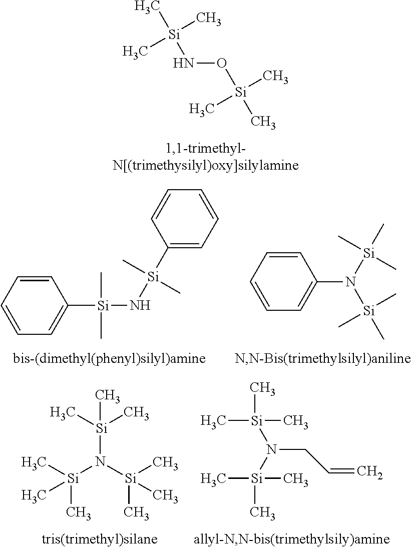

Silicon-containing precursors including a plurality of Si—N bonds may include, but is not limited to, materials according to Formula 1, where each R may individually be selected from a methyl group, an alkyl, an alkoxy, or a halide. As illustrated in Formula 1, the silicon-containing precursor, which may be a silicon-and-nitrogen-containing precursor, may be characterized by a plurality of SiX_{y} groups bonded to a nitrogen atom, wherein X is hydrogen, a methyl group, an alkyl, an alkoxy, or a halide.

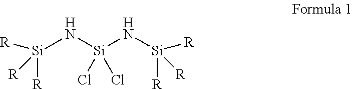

Silicon-containing precursors including a ring having at least one nitrogen atom may be, but are not limited to:

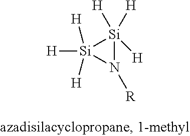

The silicon-containing precursor may be provided with one or more diluents or carrier gases such as an inert gas or other gas delivered with the silicon-containing precursor. As such, method 200 may include providing one or more inert gases or other gases at operation 210.

A flow rate of silicon-containing precursor provided to the processing region at operation 210 may be selected to provide sufficient functional groups to react with the undesirable terminations 325 within the one or more pores 315 to form desirable terminations 320. In embodiments, a flow rate of the silicon-containing precursor may be greater than or about 1 sccm, and may be greater than or about 10 sccm, greater than or about 50 sccm, greater than or about 100 sccm, greater than or about 250 sccm, greater than or about 500 sccm, greater than or about 1,000 sccm, greater than or about 1,500 sccm, greater than or about 2,000 sccm, greater than or about 3,000 sccm, greater than or about 4,000 sccm, greater than or about 5,000 sccm, greater than or about 6,000 sccm, or more. However, at increased flow rates, excessive silicon-containing precursor may be present and further benefit of the increased flow rate may not be realized.

Some embodiments may include forming plasma effluents of the silicon-containing precursor at optional operation 215. The plasma power applied may be a lower power plasma, which may reduce dissociation and control the amount of plasma effluents formed. However, the plasma power may be sufficient to fragment one or more of the functional groups from the silicon-containing precursor. Accordingly, in some embodiments, and depending on the silicon-containing precursor used, a plasma power source may deliver a plasma power to the faceplate, chamber, or substrate support of less than or about 5,000 W, and may deliver a power of less than or about 4,500 W, less than or about 4,000 W, less than or about 3,500 W, less than or about 3,000 W, less than or about 2,500 W, less than or about 2,000 W, less than or about 1,500 W, less than or about 1,000 W, less than or about 500 W, less than or about 250 W, less than or about 200 W, less than or about 150 W, less than or about 100 W, less than or about 75 W, less than or about 50 W, or less.

While some embodiments may include forming plasma effluents of the silicon-containing precursor, it is contemplated that the processing region is maintained plasma-free while providing the silicon-and-nitrogen-containing precursor and while contacting the layer of silicon-containing material with the silicon-containing precursor.

At operation 220, method 200 may include contacting the layer of material 310 with the silicon-containing precursor. Contacting the layer of silicon-containing material with the silicon-containing precursor may fragment the silicon-containing precursor. As illustrated in FIG. 3B, the fragmenting may introduce one or more functional groups within the one or more pore 315. The one or more functional groups may reorganize bonds within the one or more pores 315. This reorganization may reduce undesirable terminations 325, such as Si—OH bonds and/or Si—H bonds, within the one or more pores 315. The reorganization may simultaneously increase desirable terminations 320, such as Si-CH3 bonds, Si—NH bonds, Si—NH2 bonds, and/or Si—O—Si crosslinking, within the one or more pores 315. By increasing desirable terminations 320 while reducing undesirable terminations 325, the contacting may reduce the dielectric constant of the layer of material 310. The reduction in dielectric constant may repair damage caused by the integration operation at optional operation 205. In embodiments, the contacting may reduce the dielectric constant of the layer of material 310 below a dielectric constat of the layer of material 310 prior to the integration operation.

Additionally, as fragmenting of the silicon-containing precursor occurs, the size of the silicon-containing precursor may reduce and may allow a remaining portion of the silicon-containing precursor to diffuse further into one of the one or more pores 315. As such, as illustrated in FIG. 3C, as the silicon-containing precursor continues to fragment and reduce in size, the remaining portion of the silicon-containing precursor may diffuse into restricted spaces or areas within the one or more pores 315, such as spaces or areas that the un-fragmented silicon-containing precursor would not be able to access. It is contemplated that the fragmentation may continue until no functional groups remain.

Temperature may impact operations of the present technology. For example, the method 200, such as the repair at operation 210-220, may be performed at a temperature less than or about 600° C., and may be performed at a temperature less than or about less than or about 550° C., less than or about 500° C., less than or about 450° C., less than or about 400° C., less than or about 350° C., less than or about 300° C., less than or about 250° C., less than or about 200° C., less than or about 150° C., less than or about 100° C., less than or about 50° C., or less. Additionally, the method 200, such as the repair at operation 210-220, may be performed at a temperature greater than or about 50° C., and may be performed at a temperature greater than or about 100° C., greater than or about 150° C., greater than or about 200° C., greater than or about 250° C., greater than or about 300° C., greater than or about 350° C., greater than or about 400° C., greater than or about 450° C., greater than or about 500° C., greater than or about 550° C., greater than or about 600° C., or more. The temperature may be maintained in any of these ranges throughout the method 200, including during the integration operation and the repair. However, it is also contemplated that the temperature may be adjusted between operations.

Pressure may also impact operations of the present technology. For example, the method 200, such as the repair at operation 210-220, may be performed at a pressure less than or about 600 Torr, and may be performed at a pressure less than or about 500 Torr, less than or about 400 Torr, less than or about 300 Torr, less than or about 200 Torr, less than or about 100 Torr, less than or about 50 Torr, less than or about 30 Torr, less than or about 20 Torr, less than or about 10 Torr, less than or about 5 Torr, less than or about 1 Torr, or less. Additionally, the method 200, such as the repair at operation 210-220, may be performed at a pressure greater than or about 1 Torr, and may be performed at a pressure greater than or about 5 Torr, greater than or about 10 Torr, greater than or about 20 Torr, greater than or about 30 Torr, greater than or about 50 Torr, greater than or about 100 Torr, greater than or about 200 Torr, greater than or about 300 Torr, greater than or about 400 Torr, greater than or about 500 Torr, greater than or about 600 Torr, or more. The pressure may be maintained in any of these ranges throughout the method 200, including during the integration operation and the repair. However, it is also contemplated that the pressure may be adjusted between operations.

Conventional technologies may be limited to precursors that cannot diffuse further into the one or more pores 315. Conversely, the present technology may better repair the layer of material 310 within the one or more pores 315 through the use of multi-functional silicon-containing precursors. Therefore, the present technology may be able to repair low-κ materials after integration operations as well as further reduce dielectric constants of low-κ materials after deposition operations.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a silicon-containing precursor” includes a plurality of such precursor, and reference to “the layer of silicon-containing material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a silicon-containing precursor having multiple functional groups to a processing region of a semiconductor processing chamber, wherein a substrate is housed within the processing region, and wherein the substrate comprises a layer of silicon-containing material defining one or more pores; and
contacting the layer of silicon-containing material with the silicon-containing precursor, wherein the silicon-containing precursor diffuses into the one or more pores and reduces Si—OH bonds and/or Si—H bonds within the one or more pores.

2. The semiconductor processing method of claim 1, further comprising:
forming plasma effluents of the silicon-containing precursor. 2

3. The semiconductor processing method of claim 1, wherein the silicon-containing precursor further comprises nitrogen.

4. The semiconductor processing method of claim 3, wherein the silicon-containing precursor comprises a single nitrogen with multiple functional groups bonded to the single nitrogen.

5. The semiconductor processing method of claim 3, wherein the silicon-containing precursor comprises a plurality of Si—N bonds.

6. The semiconductor processing method of claim 3, wherein the silicon-containing precursor comprises a ring having at least one nitrogen atom.

7. The semiconductor processing method of claim 1, wherein contacting the layer of silicon-containing material with the silicon-containing precursor fragments the silicon-containing precursor.

8. The semiconductor processing method of claim 7, wherein, subsequent to fragmenting the silicon-containing precursor, a remaining portion of the silicon-containing precursor diffuses further into one of the one or more pores.

9. The semiconductor processing method of claim 1, wherein contacting the layer of silicon-containing material with the silicon-containing precursor increases an amount of Si—CH₃ bonds within the one or more pores.

10. The semiconductor processing method of claim 1, wherein contacting the layer of silicon-containing material with the silicon-containing precursor increases an amount of Si—O—Si crosslinking within the one or more pores.

11. The semiconductor processing method of claim 1, wherein contacting the layer of silicon-containing material with the silicon-containing precursor reduces a dielectric constant of the layer of silicon-containing material.

12. The semiconductor processing method of claim 1, further comprising:
performing an integration operation prior to providing the silicon-containing precursor having multiple functional groups to the processing region, wherein the integration operation increases Si—OH bonds and/or Si—H bonds within the one or more pores.

13. The semiconductor processing method of claim 12, wherein the integration operation comprises one or more of planarization, etching, ashing, or cleaning.

14. A semiconductor processing method comprising:
providing a silicon-containing precursor having multiple functional groups to a processing region of a semiconductor processing chamber, wherein the silicon-containing precursor further comprises, wherein a substrate is housed within the processing region, and wherein the substrate comprises a layer of silicon-containing material defining one or more pores; and
contacting the layer of silicon-containing material with the silicon-containing precursor, wherein contacting the layer of silicon-containing material with the silicon-containing precursor increases an amount of Si—O—Si crosslinking within the one or more pores.

15. The semiconductor processing method of claim 14, wherein the silicon-containing precursor is characterized by a plurality of SiX_{y} groups bonded to a nitrogen atom, wherein X is hydrogen, a methyl group, an alkyl, an alkoxy, or a halide.

16. The semiconductor processing method of claim 14, wherein the processing region is maintained plasma-free while providing the silicon-containing precursor and while contacting the layer of silicon-containing material with the silicon-containing precursor.

17. The semiconductor processing method of claim 14, wherein contacting the layer of silicon-containing material with the silicon-containing precursor reduces Si—OH and/or Si—H bonds within the one or more pores.

18. A semiconductor processing method comprising:
providing a silicon-containing precursor having multiple functional groups to a processing region of a semiconductor processing chamber, wherein the silicon-containing precursor further comprises nitrogen, wherein a substrate is housed within the processing region, and wherein the substrate comprises a layer of silicon-containing material defining one or more pores; and
contacting the layer of silicon-containing material with the silicon-containing precursor, wherein contacting the layer of silicon-containing material with the silicon-containing precursor fragments the silicon-containing precursor, and wherein a remaining portion of the silicon-containing precursor diffuses further into one of the one or more pores.

19. The semiconductor processing method of claim 18, wherein contacting the layer of silicon-containing material with the silicon-containing precursor reduces Si—OH bonds and/or Si—H bonds within the one or more pores.

20. The semiconductor processing method of claim 18, wherein contacting the layer of silicon-containing material with the silicon-containing precursor increases an amount of Si—O—Si crosslinking within the one or more pores.
